(19) United States
(12) Patent Application Publication
(10) Pub. No.: US 2016/0260586 A1
(43) Pub. Date: Sep. 8, 2016

(54) DRY ETCHING DEVICE AND DRY ETCHING METHOD

(71) Applicant: SHENZHEN CHINA STAR OPTOELECTRONICS TECHNOLOGY CO., LTD., Shenzhen, Guangdong (CN)

(72) Inventor: Li CHAI, Shenzhen (CN)

(21) Appl. No.: 14/406,694

(22) PCT Filed: Jun. 3, 2014
(86) PCT No.: PCT/CN2014/079080

§ 371 Date: Dec. 9, 2014

(30) Foreign Application Priority Data
May 23, 2014 (CN) 201410221953.0

(51) Int. Cl. H01J 37/32

(52) U.S. Cl. CPC H01J 37/32449; H01J 37/32009

(57) ABSTRACT

The present disclosure disclosed a dry etching device, comprising an etching cavity; a gas extraction system arranged on the bottom of the etching cavity, wherein, the system includes a gas passage, a gas extractor; controllable valves, each mounted on a respective gas inlet. The present disclosure disclosed a dry etching method, including the steps of: placing a workpiece to be etched on a base platform in an etching cavity; selecting a gas extraction mode from a group consisting of a circulatory working mode and a non-circulatory working mode according to procedures to be performed; performing a dry etching procedure while extracting gas under the circulatory mode or non-circulatory mode. The device can improve the uniformity of the dry etching process and the substrate to be manufactured, thus increase the quality of the product. In addition, the restriction to the design of the product due to the considerations of the uniformity can be reduced, and thus enlarge the room for designing the products.

### CROSS REFERENCE OF RELATED APPLICATION

The present disclosure claims the priority of Chinese Application CN201410221953.0, filed in Chinese Patent Office on May 23, 2014, and entitled “DRY ETCHING DEVICE AND DRY ETCHING METHOD”, the entire contents of which are herein incorporated by reference.

### FIELD OF THE INVENTION

The present disclosure relates to the field of semiconductor machining, in particular to a dry etching device and a method for dry etching.

### BACKGROUND OF THE INVENTION

With the development of information society, demands of people on display device have grown, thus promoting the rapid development of the liquid crystal panel industry, and increasing the yield of panels continuously. An etching process is an important step in the process of manufacturing a thin film transistor liquid crystal display (Thin Firm Transistor Liquid Crystal Display, referred to as TFT-LCD) array substrate. The etching process is divided into a dry etching process and a wet etching process according to the physical state of an etching agent. The dry etching process is a process for etching by using an etching gas, and the wet etching process is a process for etching by using an etching liquid.

In a TFT-LCD machining and manufacturing process using the dry etching process, at an ideal state, the etching gas is blown to a substrate surface to be machined in a direction exactly perpendicular to the substrate surface to be machined, under the action of such factors as a blowing force of an intake system, a suction force of a gas extraction system, a voltage between plate electrodes and the like. In the entire machining process, the stability of the gas pressure and the gas flow of the etching gas is ensured, to ensure that the volume of the etching gas contacted by each part of the substrate surface to be machined in the entire machining process is equal, so as to ensure that the parts of a substrate to be machined are treated at the same rate and ensure the machining uniformity of the parts of the substrate to be etched in the machining process. But due to such factors as an internal design structure of an etching cavity, an exhaust system design and the like, in actual operation, the flow direction of the etching gas is not exactly perpendicular to the substrate surface to be etched, and the flow rates of the etching gas flowing by the parts of the parts of the substrate surface to be etched are not exactly the same. The result is that the volumes of the etching gas blown to the parts of the substrate to be machined in the entire etching process are not exactly the same, resulting in that the etching degrees of the parts of the substrate to be etched are different, and the etching uniformity of the parts of the substrate to be etched cannot be well ensured.

But with the development and progress of society, demands of people on the display device grow continually, and requirements of people on the quality of liquid crystal panels are higher as well. In order to pursue a higher quality of liquid crystal panels and a higher production yield of the liquid crystal panels, the requirements on the machining uniformity of the parts of the substrate to be machined in the liquid crystal panel machining process are higher. Meanwhile, for dry etching device used for machining other substrates by using the dry etching process, the requirements on the process uniformity thereof are also rising continuously.

Therefore, in order to better ensure the process uniformity of different parts of the substrate to be machined in the machining process, a new device and method for dry etching process is needed.

### SUMMARY OF THE INVENTION

Aiming at the problem of low process uniformity of dry etching machining in the prior art, the present disclosure provides a dry etching device, including:

an etching cavity, including a base platform for placing a workpiece to be etched thereon; and

a gas extraction system arranged on the bottom of the etching cavity for controlling the movement of gas flow in the etching cavity, wherein the gas extraction system includes:
a gas passage provided with a plurality of gas inlets and a gas outlet, the gas inlets extending into the cavity through an opening located on the bottom of the cavity;
a gas extractor arranged in the gas passage and adjacent to the gas outlet;
controllable valves, each mounted on a respective gas inlets and configured to be opened/closed according to setting parameters;

wherein the gas extraction system operates in a circulatory mode and a non-circulatory mode, and under the circulatory mode, the controllable valves are sequentially opened/closed at a certain time interval so as to control the flow direction of etching gas in the cavity, so that average densities of the etching gas flowing through the workpiece to be etched and thus contacting with different positions of the workpiece to be etched in a specific procedure are consistent.

In one embodiment, with respect to the non-circulatory mode, the controllable valves are all opened to extract gas.

In one embodiment, in the circulatory mode, the controllable valves are controlled to gradually change the flow direction of etching gas in the cavity, in order to ensure the stability of the gas flow in the etching cavity.

In one embodiment, under the circulatory mode, the controllable valves are controlled to enable the gas extraction system to extract a constant volume of gas per unit time, in order to keep the gas pressure in the etching cavity unchanged.

In one embodiment, under the circulatory mode, the opening/closing time interval of the controllable valves is determined by the duration of the specific procedure.

In one embodiment, the number and positions of the gas inlets are determined by at least one of the shape of an electrode of the dry etching device, the shape of the base platform and the shape of a surface to be etched of the workpiece.

In one embodiment, the gas inlets are located on the bottom of the etching cavity and are equidistantly arranged on the periphery of the base platform.

In one embodiment, under the circulatory mode, the controllable valves on adjacent positions are controlled to alternatively open/close, in order to slowly change the flow direction of the etching gas in the cavity.

In one embodiment, under the circulatory mode, the controllable valves are controlled in such a manner that the increment of the gas extraction volume per unit time at the controllable valves during an opening process is equal to the decrement of the gas extraction volume per unit time at the controllable valves in a closing process, thus keeping the total gas extraction volume of the passage per unit time unchanged.

In one embodiment, under the circulatory working mode, the controllable valves are controlled in such a manner that the opening degrees of the controllable valves in an opening process are equal to the closing degrees of the controllable valves in a closing process.

The present disclosure further provides a method for dry etching a workpiece, including the following steps:

placing a workpiece to be etched on a base platform in an etching cavity;

selecting a gas extraction mode from a group consisting of a circulatory working mode and a non-circulatory working mode according to procedures to be performed;

controlling, when the circulatory working mode is selected, the opening/closing of controllable valves according to setting parameters to control the flow direction of the etching gas, in order to make the average density of the etching gas contacting with different positions of the workpiece to be etched in a specific procedure tend to be consistent; and

performing a dry etching procedure while extracting gas in the circulatory working mode or non-circulatory working mode.

In one embodiment, a gas extraction system of a dry etching device operates under the circulatory working mode when the dry etching device performs a main etching procedure.

Compared with the prior art, the present disclosure has the following advantages:

the dry etching device designed according to the present disclosure can further better the uniformity of the dry etching process and improve the manufacturing uniformity of array substrates, so as to improve the product quality and yield.

The dry etching device designed according to the present disclosure further reduces the limit of the design affected by the process uniformity, thereby improving the space of the design.

Other features and advantages of the present disclosure will be set forth in the following description, and in part will be made obvious from the description, or be learned by implementing the present disclosure. The objectives and other advantages of the present disclosure can be achieved and obtained by structures particularly pointed out in the description, the claims and the accompanying drawings.

### BRIEF DESCRIPTION OF THE DRAWINGS

The accompanying drawings are configured to provide a further understanding of the present disclosure, constitute a part of the description, and explain the present disclosure together with the embodiments of the present disclosure without limiting the present disclosure. In the accompanying drawings:

FIG. 1 is a block diagram of a structure of dry etching device in the prior art;

FIG. 2 and FIG. 3 are block diagrams of structure of dry etching device according to an embodiment of the present disclosure;

FIG. 4 is a top view of the structure of dry etching device according to an embodiment of the present disclosure;

FIG. 5a and FIG. 5b are top views of the structure of dry etching device according to an embodiment of the present disclosure respectively;

FIG. 6 is a schematic diagram of the shape of a gas inlet of a gas extraction system according to the present disclosure;

FIG. 7 is an operation flowchart of a gas extraction system of dry etching device according to an embodiment of the present disclosure;

FIG. 8 is an operation flowchart of a gas extraction system of dry etching device according to an embodiment of the present disclosure;

FIG. 9 is an operation flowchart of dry etching device according to an embodiment of the present disclosure; and

FIG. 10 is an operation flowchart of dry etching device according to an embodiment of the present disclosure.

### DETAILED DESCRIPTION OF THE EMBODIMENTS

A detailed description of the implementation of the present disclosure will be given below, in combination with the accompanying drawings and embodiments. Therefore, an implementation process of how to use technical means of the present disclosure to solve technical problems and achieve a technical effect may be fully understood and implemented accordingly. It should be noted that, as long as no conflict is generated, various embodiments in the present disclosure and various features in the embodiments can be mutually combined, and the formed technical solutions are all within the scope of the present disclosure.

In a manufacturing process of an integrated circuit of electronic device, an entire circuit diagram generally needs to be defined on the surface of a workpiece. The manufacturing procedures thereof generally include: firstly covering a layer of thin film on the surface of the workpiece to be machined, defining a circuit pattern on this layer of thin film through light resistance by using lithography, and removing the unnecessary parts in a chemical or physical manner, wherein this removing step is called etching. In an etching process, the etching degree of the entire workpiece under a certain process is generally described by process uniformity. In a specific process, the closer the etching degrees of different positions on the same machined surface of the workpiece are, the higher the process uniformity is. To ensure that etching machining of the parts of the workpiece can be finished at the same time, and ensure the workpiece machining yield and the workpiece quality, the etching degrees of the parts of the workpiece need to be controlled, and it is should be ensured as far as possible that the parts of the workpiece to be etched are etched at the same rate. Namely, higher process uniformity is ensured in the etching process.

In the prior art, the etching process is generally divided into a wet etching process and a dry etching process. As the name implies, the wet etching process is to etch by adopting a liquid as a medium, and the dry etching process is to etch by adopting a gas as a medium. So for the dry etching process, in the entire process, the volume of the etching gas contacted by the surface to be machined of the workpiece to be machined becomes an important determinant of determining the etching rate. Under normal circumstances, the process uniformity of the dry etching device is mainly perfected by regulating such parameters as pressure, gas flow or the like. However, with the continuously increasing requirements on the process uniformity, the process uniformity is very difficult to be further improved just by regulating the above-mentioned several parameters. In particular, the workpeices to be machined become bigger and bigger at present, the difficulty of improving the process uniformity is also getting larger and larger.

Therefore, the present disclosure is provided to overcome the design defects of the existing dry etching device mechanism and the difficulty to improve the uniformity. Since the gas extraction system in the existing dry etching device has a single function, the distribution of a process gas affected by the gas extraction system is fixed, in the present disclosure, the gas extraction system of the dry etching device is optimized and improved, to perfect the flow direction of the etching gas in the machining process, to control the volumes of the etching gas contacted by different positions of the surface to be machined of the workpiece to be machined in the entire process, so as to improve the process uniformity.

The dry etching device of the present disclosure can be adopted to improve the process uniformity. Herein, the operation mode of the present disclosure is described mainly based on the dry etching device for machining TFT liquid crystal display panels, and thereafter, glass substrates are mainly machined and treated in the etching process. But it should be noted that, the application of the dry etching device of the present disclosure is not limited hereto, the dry etching device of the present disclosure can be adopted in any machining and manufacturing procedures concerning the dry etching process.

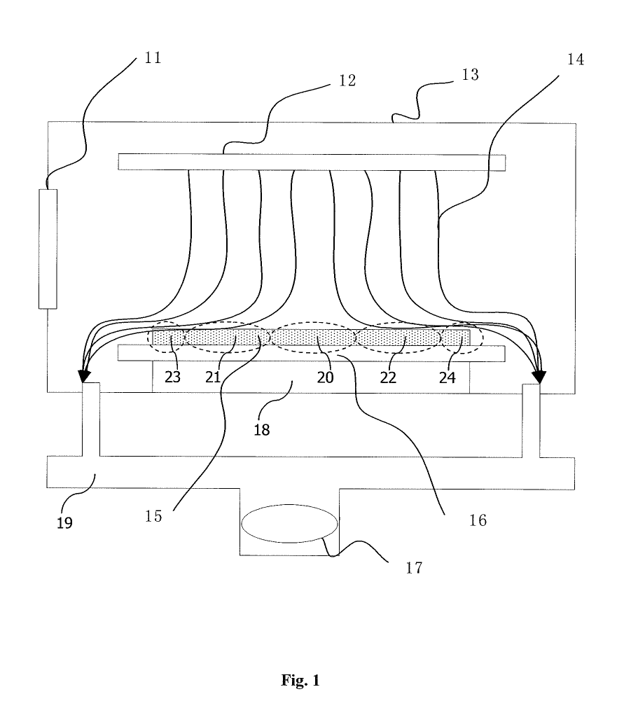

FIG. 1 is a schematic diagram of existing dry etching device. As shown in FIG. 1, the dry etching device includes: an etching cavity 13 for etching; a cavity door 11 arranged on the side face of the etching cavity 13 for conveying a substrate 15; a base platform 18 placed on the bottom of the etching cavity 13 for supporting the substrate 15; an upper electrode 12 and a lower electrode 16 for controlling the flow direction of an etching gas; and a gas extraction system 19 placed on the bottom of the etching cavity 13 of the dry etching device for exhausting the etching gas. An intake system of the dry etching device is built on the electrode 12 on the top of the etching cavity 13 and is used for blowing in the etching gas, and since the position of the intake system is overlapped with the upper electrode 12, it is not shown in FIG. 1.

When etching by using the dry etching device as shown in FIG. 1, a constant differential pressure is generated between the upper electrode 12 and the lower electrode 16 firstly, and then the etching gas is blown into the etching cavity 13 through the intake system. The etching gas is blown to the surface to be machined of the substrate 15 in a direction from top to bottom under the action of a blowing force of the intake system, a suction force of the gas extraction system 19 and a voltage between the upper electrode 12 and the lower electrode 16. The actual flow direction of the etching gas is shown by an arrow line at a mark 14, and the etching gas blown onto the surface to be machined flows from the center of the surface to be machined to the edge and is extracted by the gas extraction system 19 downwards along the edge of the substrate.

Since the gas extraction system 19 only has a large gas extraction passage, when the etching gas flow acts on the glass substrate, the gas disperses to the surrounding of the substrate, due to the traction of a gas suction force on the surrounding of the substrate, the gas in a transitional region between the middle of the substrate and the edge is consistently at a transverse flow state, which results in low etching efficiency. It can be seen from the flow line of the etching gas at the mark 14 in FIG. 1 that, the flow directions of the etching gas flowing by the central region 20 of the substrate, the peripheral regions 21 and 22 of the substrate and the edge regions 23 and 24 of the substrate are different, the flow rates of the etching gas flowing by different positions of the substrate are different as a result, such that the contact densities of the etching gas contacted with different positions of the substrate within the unit time are different. A rough description is that, the contact density of the etching gas contacted with the central region 20 and the edge regions 23 and 24 of the substrate is smaller than that of the etching gas contacted with the peripheral regions 21 and 22 of the substrate. Therefore, when etching a material comparably sensitive to the etching gas, the etching rate of the central region 20 and the edge regions 23 and 24 of the substrate is smaller than that of the peripheral regions 21 and 22 of the substrate.

Since in the FIG. 1, the gas extraction system only includes one gas extractor 17 and the gas extraction manner is unchanged, under the condition that the intake manner of the intake system is unchanged and the differential pressure between the upper electrode 12 and the lower electrode 16 is unchanged, the flow direction of the etching gas in the etching cavity 13 is unchanged. Base on the above-mentioned condition, after a period of etching time, the etching degree of the central region 20 and the edge regions 23 and 24 of the substrate is smaller than that of the peripheral regions 21 and 22 of the substrate, such that the uniformity of the substrate is reduced, and the quality of the machined substrate is affected as a result. Even, when this condition is severe, it will result in failures of machining the substrate, thereby reducing the etching yield.

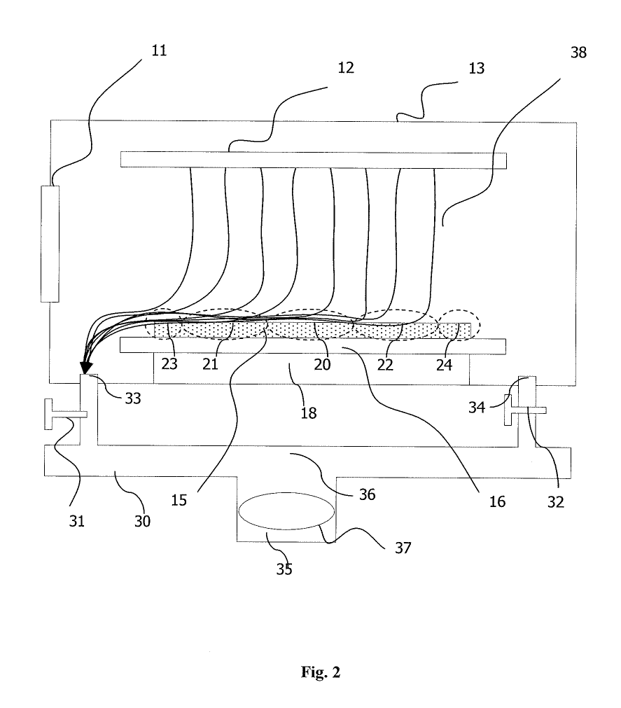

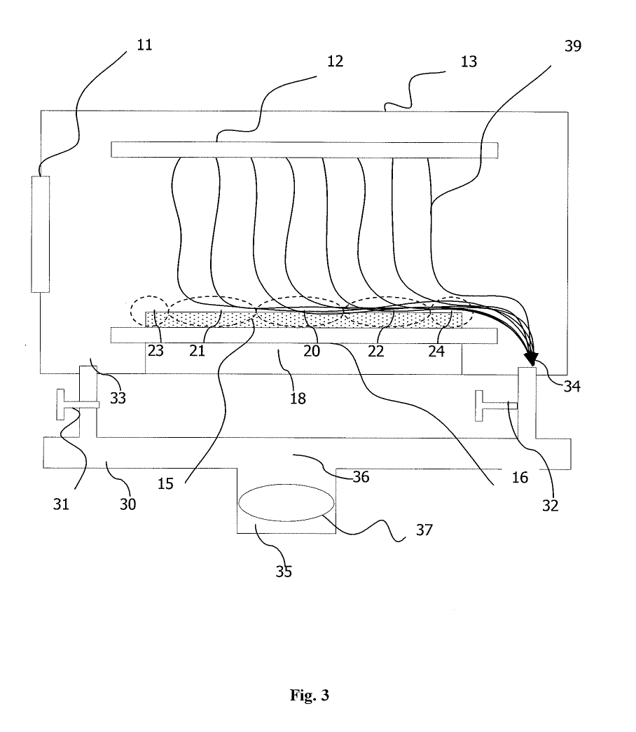

In order to improve the etching process uniformity of the substrate, the present disclosure improves the dry etching device, and particularly improves the gas extraction system of the dry etching device. The dry etching device adopting the gas extraction system of an embodiment of the present disclosure is as shown in FIG. 2 and FIG. 3. Under the condition that no gas extraction system is included, the structure of the dry etching device as shown in FIG. 2 and FIG. 3 is completely the same as that shown in FIG. 1, and will not be repeated redundantly herein. A gas extraction system 30 is spanned on the bottom of the etching cavity 13 of the dry etching device. It includes a gas passage 36, controllable valves 31 and 32 and a gas extractor 37. Wherein, the gas passage 36 is provided with gas inlets 33 and 34 and a gas outlet 35. The gas inlets 33 and 34 are extended into the cavity through an opening on the bottom of the cavity and are respectively arranged on the two sides of a base platform 18 which is the center. When the gas extraction system operates, a gas enters the passage 36 through the gas inlets 33 and 34 under the action of the suction force of the gas extractor 37, and then is exhausted from the outlet 35.

The controllable valves 31 and 32 of the gas extraction system 30 are configured to open/close according to set parameters. The controllable valves 31 and 32 can control the opening/closing degree thereof, so as to control the gas extraction volumes of the gas inlets 33 and 34 within a unit time. In this embodiment, the gas extraction system 30 has a circulatory working mode and a non-circulatory working mode. Wherein, under the non-circulatory working mode, the controllable valves 31 and 32 are simultaneously opened to extract gas; under the circulatory mode, the controllable valves 31 and 32 are sequentially opened/closed at a certain time interval, to control the flow direction of an etching gas in the cavity, so as to ensure a consistent average contact density of the etching gas flowing by different positions of the workpiece to be etched in a specific procedure. Of course, under an actual condition, the average contact density of the etching gas flowing by different positions of the workpiece to be etched cannot be completely the same. Therefore, the consistency herein discussed can only be approximate. Similarly, in the following description in this specification, the consistency does not refer to complete identity, but is an approximately identical state.

Meanwhile, according to different states of the controllable valves 31 and 32 of the gas extraction system 30, the gas extraction system 30 under the circulatory mode can also be subdivided into two working states. The first working state is as shown in FIG. 2. In the first working state, the controllable valve 31 is opened and the controllable valve 32 is closed, such that the etching gas enters the gas passage 36 through the gas inlet 33, and the gas extraction volume at the gas inlet 34 per unit time is 0. Under this condition, the flow direction of the etching gas under the action of the upper electrode 12, the lower electrode 16, the intake system and the gas extraction system 30 is shown by an arrow mark 38.

Similarly, the second working state of the gas extraction system 30 is as shown in FIG. 3. In the second working state, the controllable valve 32 is opened and the controllable valve 31 is closed, such that the etching gas enters the gas passage 36 through the gas inlet 34, and the gas extraction volume at the gas inlet 33 per unit time is 0. Under this condition, the flow direction of the etching gas under the action of the upper electrode 12, the lower electrode 16, the intake system and the gas extraction system 30 is shown by an arrow mark 39.

With respect to one single working state of the gas extraction system 30, the flow directions and flow rates of the etching gas on different positions of the substrate 15 are different, thus in a working state, the contact densities of the etching gas contacted with different positions of the substrate 15 per unit time are different, while in the entire working state, the total volumes of the etching gas contacted by different positions of the substrate 15 are different. However, incorporating the two working states of the gas extraction system 30, the first working state and the second working state, in the horizontal direction, the flow directions of the etching gas are opposite, and the total volumes of the etching gas flowing in opposite directions in the entire working state is approximately complementary. Namely, in the first working state, the total volume of the etching gas contacted by the substrate 15 is smaller relative to other regions, and in the second working state, the total volume of the etching gas contacted by the substrate is larger relative to other regions. Thus as a whole, in the two working states, the total volumes of the etching gas contacted by different positions of the substrate 15 are consistent, thereby improving the process uniformity of the substrate.

The sequential execution of the two working states is taken as a gas extraction cycle, in the etching process, the gas extraction cycle is completely and repeatedly executed to make the total volumes of the etching gas contacted with different portions of the substrate 15 in the entire etching process tend to be uniform, thereby ensuring the consistent etching degree of different positions of the substrate 15 in the entire etching process, and ensuring the quality and yield of the etching to the maximum.

In the dry etching process, because the gas pressure in the etching cavity of the dry etching device needs to be kept at a constant value, which requires that the total gas extraction volume of the gas extraction system needs to be set according to the gas pressure value in the cavity and the total intake volume of the intake system before the gas extraction system is operated. Moreover, in the entire etching process, if the total intake volume per unit time of the intake system is unchanged, the total gas extraction volume per unit time of the gas extraction system cannot change. Namely, the controllable valves of the dry etching device are controlled to enable the gas extraction system to extract gas at a constant total gas extraction volume per unit time, so as to keep the gas pressure in the etching cavity unchanged. This requires that, when the gas extraction system of this embodiment is operated, in the increase/decrease process of the gas extraction volume of one gas inlet within the unit time, the gas extraction volume of the other gas inlet equally increases/decreases within the unit time, namely, the working states are switched on the premise of ensuring that the total gas extraction volumes per unit time of the two gas inlets are kept unchanged, in order to avoid unstable gas pressure in the etching cavity caused by insufficient or excessive gas extraction.

In a normal operation process of the gas extraction system of the present disclosure, the controllable valves is required to slowly change the flow direction of the etching gas in the cavity, so as to maintain the stability of the gas flow in the etching cavity. Namely, the change of the gas extraction volume per unit time of any gas inlet cannot be too fast, meanwhile, the suction position of the gas extraction system for sucking the etching gas cannot be changed quickly neither, because the rapid change of the above-mentioned both will result in rapid change of the flow direction and flow rate of the etching gas to affect the stability of the gas flow in the etching cavity. In this embodiment, when switching the working state, the gas extraction system slowly decreases the gas extraction volume per unit time of one gas inlet to zero (the gas inlet is closed), meanwhile slowly opens the other gas inlet and gradually increases the gas extraction volume thereof per unit time, when one gas inlet just reaches the closing state, the other gas inlet is ensured to just reach the maximum value of the gas extraction volume per unit time of the system, to consistently meet the principle that the sum of the opening degrees of two converting passages is equal to the opening degree of one passage, in order to avoid unstable pressure in the etching cavity caused by insufficient or excessive gas extraction.

The above-mentioned embodiment is merely an embodiment of the present disclosure. In the above-mentioned embodiment, the gas extraction system 30 is designed only considering complementary flow directions of the etching gas in a pair of opposite directions on the horizontal plane of the substrate. The gas extraction system 30 only includes two gas inlets, of course, in actual operation, the flow directions of the etching gas in a plurality of directions on the horizontal plane of the substrate need to be considered according to actual conditions. Therefore, in actual operation, such parameters as number, installation positions, gas extraction change per unit time or the like of the gas inlets may be designed according to the factors such as the shape of the surface to be machined, the shapes of the upper and lower electrodes, the shape of a base of the substrate and so on, to achieve more accurate control of the flow direction of the etching gas, and make the total volumes of the etching gas contacted with different portions of the substrate be consistent in a gas extraction cycle.

For example, in another embodiment of the present disclosure, the shapes of the electrodes of the dry etching device, the surface to be machined of the substrate and the base are quadrangles. In this embodiment, the gas extraction system considers the flow directions of the etching gas in the front, back, left and right directions on the substrate plane based on the shapes of the electrodes. Therefore, in the embodiment as shown in FIG. 4, the gas extraction system includes four gas inlets. FIG. 4 is a top view of a substrate of dry etching device, as shown in FIG. 4, gas inlets 41, 42, 43, 44 are equidistantly installed on the surrounding of a substrate 45, and each gas inlet is correspondingly placed at one side of the substrate 45.

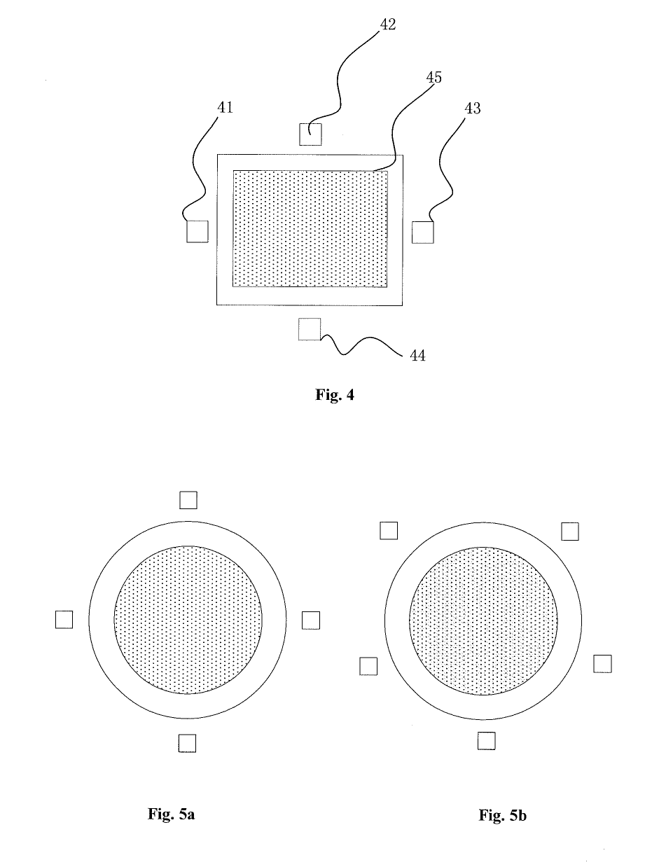

The gas inlets of the gas extraction system of the dry etching device in the present disclosure are designed to control the flow direction of the etching gas in the etching cavity. Therefore, the design of the gas inlets of the gas extraction system of the dry etching device in the present disclosure is not limited to the conditions described in the above-mentioned embodiment. Through ensuring the consistency of total gas volumes of the etching gas blown to different positions of a region to be etched of the substrate within a gas extraction cycle, and considering the change of the gas extraction volumes of the gas inlets within the unit time, the number and the position of the gas inlets can be designed in a variety of forms. For example, in another embodiment of the present disclosure as shown in FIG. 5a and FIG. 5b, the shapes of the electrodes of the dry etching device, the surface to be etched of the substrate and the base are round. In this embodiment, the gas inlets can be designed to four gas inlets as shown in FIG. 5a. Similarly, under the condition of the total gas extraction volume per unit time unchanged, the gas inlets can be designed to five gas inlets as shown in FIG. 5b in this embodiment. Of course, more gas inlets can be designed, as long as the gas inlets are equidistantly installed on the surrounding of the substrate during installation and the total gas extraction volume per unit time is ensured to be unchanged in the operation, in order to avoid unstable gas pressure in the etching cavity caused by insufficient or excessive gas extraction.

Of course, the dry etching device of the present disclosure may include one movable gas inlet. Namely, in the operation process of the system, the position of the gas inlet is movable. In this way, even if there is only one gas inlet, the gas extraction system can control the flow direction of the etching gas in the etching cavity by controlling the movement of the gas inlet. Similarly, according to another embodiment, at least one movable gas inlet can be incorporated into the design of fixed gas inlets. In this case, the control on the flow direction of the etching gas will become more complicated, and thus the control result will be more accurate. However, the most basic design purpose will not be changed, thus it will not be discussed redundantly herein.

Before the dry etching device of the present disclosure operates, the opening/closing time interval of the controllable valves and the opening/closing sequence of the controllable valves under the circulatory mode of the gas extraction system should be formulated according to the etching process duration. The working state of the gas extraction system is defined based on different opening and closing states of the controllable valves. In other words, each opening/closing of the controllable valves represents once conversion of the working states. The sequential execution of all working states is defined as a gas extraction cycle, and when the gas extraction system executes one gas extraction cycle, the flow direction of the etching gas in the etching cavity of the dry etching device just finishes a change cycle. Within one gas extraction cycle, the average contact density of the etching gas flowing by different positions of the workpiece to be etched within one gas extraction cycle is consistent.

Based on the above, when formulating the opening/closing time interval of the controllable valves, the etching process duration should be ensured to be an integral multiple of the gas extraction cycle, namely n gas extraction cycles can be completely and circularly operated within the entire etching process duration, wherein n is an integer larger than or equal to 1. In this embodiment, it is assumed that the duration of the etching process is N*t, and the duration of the gas extraction cycle of the system is set to be t. Namely, in the etching process, the gas extraction system executes the gas extraction cycle for N times.

And then, the gas extraction volume per unit time of the gas extraction system is set according to the intake volume per unit time of the intake system and the gas pressure in the etching cavity when the dry etching device operates. In the embodiment as shown in FIG. 4, the intake volume of the intake system per unit time and the gas pressure in the etching cavity when the dry etching device operates are consistent, then the total gas extraction volume per unit time should be ensured to be consistent when the system operates. In this embodiment, the gas extraction system of the dry etching device has four working states under the circulatory mode, and in any one of working states, only one gas inlet of the gas extraction system is opened. Therefore, when the gas extraction system of this embodiment is operating, and when one gas inlet is completely opened, the gas extraction volume per unit time is the total gas extraction volume per unit time of the system.

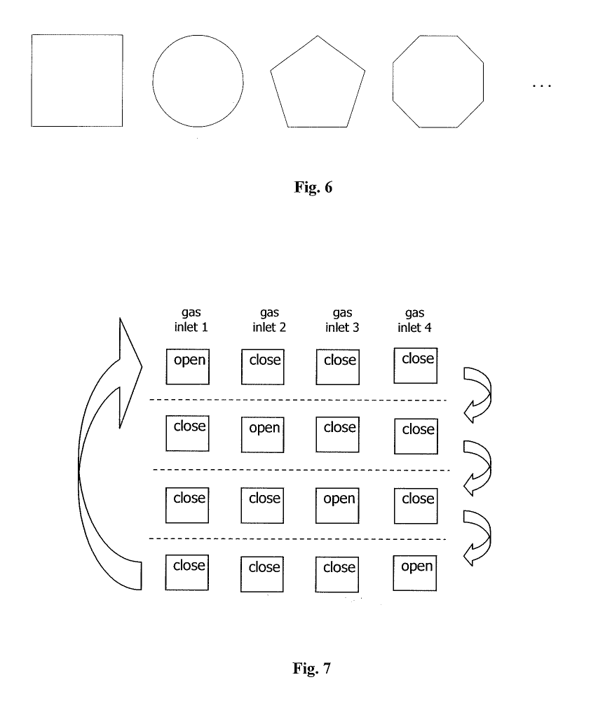

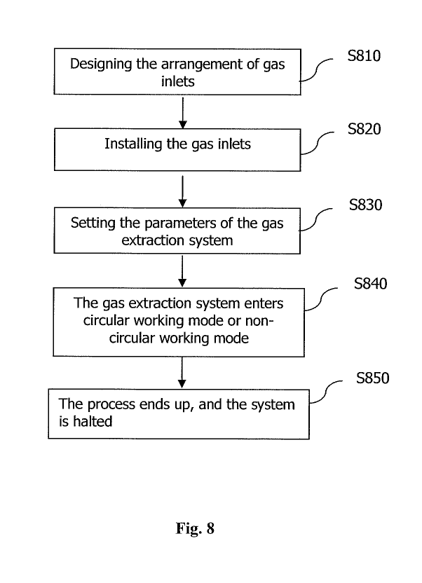

In the embodiment as shown in FIG. 4, FIG. 5a and FIG. 5b, the gas inlet of the gas extraction system is designed to a square. It is not difficult to understand that, as long as the normal operation of gas extraction is not affected, the gas inlet can be designed to any shape. As shown in FIG. 6, the shape of the gas inlet can be a square, a circle, a pentagon, an octagon or any other shape.

The sequential switch of all working states of the gas extraction system is a gas extraction cycle, namely the duration of each working state is t/4. As shown in FIG. 7: in the first working state, a gas inlet 41 opens, and the other inlets close; in the second working state, a gas inlet 42 opens, and the other inlets close; in the third working state, a gas inlet 43 opens, and the other working ports close; and in the fourth working state, a gas inlet 44 opens, and the other working ports close. The four working states are executed according to a sequence to finish a gas extraction cycle.

Of course, the gas extraction cycle is not limited to begin from the first working state. In this embodiment, the initial working cycle can be began from any working state, but in order to ensure the stability of the gas flow in the etching cavity, when the working state is switched, the adjacent gas inlet must be opened. Namely, the next adjacent gas inlet is continuously opened according to a clockwise or counterclockwise direction shown by the arrangement manner of the gas inlets in FIG. 4. Meanwhile, in the opening and closing processes of the gas inlets, in order to ensure the stability of the gas flow in the etching cavity and the consistency of the gas pressure, when the working state is switched, the gas inlets should be closed/opened slowly, and the total gas extraction volume of two gas inlets at a switch state is consistently equal to the total gas extraction volume when one gas inlet is completely opened. For example, in the first working state, the gas inlet 41 is completely opened, it is assumed that the next working state is the second working state, then the gas inlet 41 is closed slowly and the gas inlet 42 is opened slowly during switching of the states, when the gas extraction volume of the gas inlet 41 per unit time is decreased to ¼ of the maximum value, the gas extraction volume of the gas inlet 42 per unit time is just increased to ¾ of the maximum value, namely, the sum of the gas extraction volumes of the gas inlet 41 and the gas inlet 42 is consistently equal to the gas extraction volume per unit time when the gas inlet 41 or the gas inlet 42 is completely opened. Namely, the requirement that the sum of the opening degrees of two converting passages is equivalent to the opening degree of one passage is always met, in order to avoid unstable pressure in the etching cavity caused by insufficient or excessive gas extraction.

The operation mode of the gas extraction system of the present disclosure will be described below in more detail in combination with a set of flowcharts. The steps shown by the flowchart in the drawings can be executed in a computer system including for example a group of computer-executable instructions, and moreover, although a logic sequence is shown in the flowchart, in certain cases, the shown or described steps can be executed in a sequence different from that herein.

At First, considering the gas extraction system of the dry etching device only, before the dry etching device is placed in service, the internal structure thereof needs to be designed firstly. As shown in FIG. 8, with respect to the initial step S810, firstly the gas inlets of the gas extraction system are designed according to the structure of the etching cavity of the dry etching device. For example, when the shapes of the electrodes and the substrate are quadrangles, four gas inlets are designed to correspond to the four sides of the substrate, and the gas inlets are equidistantly installed on the bottom of the etching cavity surrounding the substrate as shown in FIG. 4. And then, in step S820, the gas inlets are installed in the dry etching device according to the above-mentioned design of the gas inlets.

After the gas inlets are installed, the gas extraction system needs to operate in cooperation with the operation state of the dry etching device. Before the dry etching device works, step S830 is firstly performed to set the operation parameters of the gas extraction system according to the machining procedure parameters under the dry etching process, and the parameters include opening/closing time interval of the controllable valves and opening/closing sequence of the controllable valves under the circulatory working mode or non-circulatory working mode.

After all the setting is finished, the dry etching device proceeds to the etching process. In the mean time, the gas extraction system proceeds to step S840, which is in the circulatory working mode or non-circulatory working mode. When the etching process of the dry etching device ends up, the gas extraction system proceeds to step S850 accordingly. At last, the system is halted.

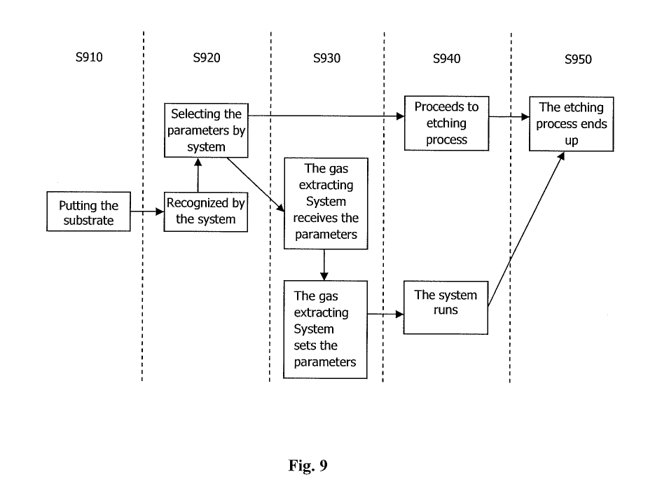

FIG. 9 describes the operation cooperation of the gas extraction system and the dry etching device through an entire operation flow of the dry etching device. As shown in FIG. 9, firstly in step S910, the substrate to be etched is placed in the dry etching device. Then, in step S920, the dry etching device identifies the parameters of the substrate to be etched to determine the machining procedure parameters of the etching process. Next, in step S930, the machining procedure parameters of the etching process are transmitted to the gas extraction system, and the gas extraction system determines its own working parameters according to the machining procedure parameters of the etching process. Namely, the gas extraction system determines which procedure should be in the circulatory working mode or non-circulatory working mode. Moreover, the gas extraction system sets the opening/closing time interval and the opening/closing sequence of its own controllable valves under the circulatory working mode or non-circulatory working mode according to the parameters in relation to the machining procedure.

And then, in step S940, the dry etching device performs an etching operation. At the same time, the gas extraction system extracts gas according to the set working parameters. Finally, in step S950, the dry etching device finishes the etching, and the process ends up. The gas extraction system is halted accordingly.

It should be noted that, in the flow chart of the embodiment as shown in FIG. 9, it is determined by the gas extraction system itself which procedure is in the circulatory working mode or non-circulatory working mode. Of course, this judgment step can also be accomplished by a dry etching device or artificially. In addition, similarly, working parameters such as opening/closing time interval and opening/closing sequence of the controllable valves of the gas extraction system under the circulatory working mode or non-circulatory working mode and the like, can be set by the dry etching device or artificially.

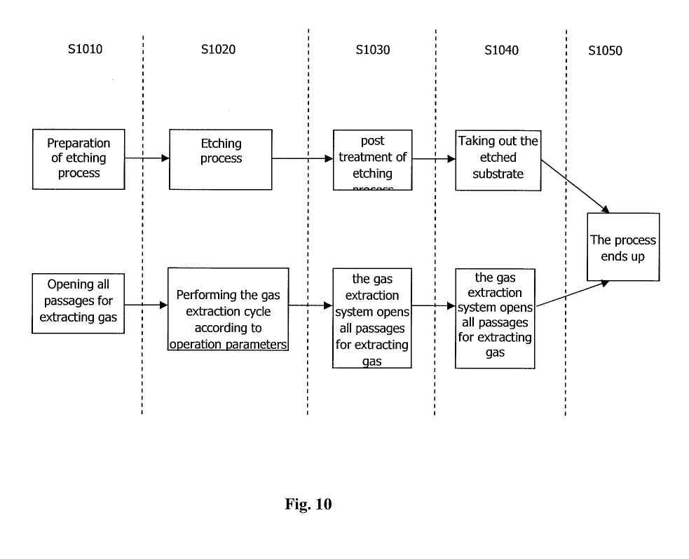

Here it should be noted that, in the flowchart of the embodiment as shown in FIG. 8 and FIG. 9, the gas extraction system works only in the etching process of the dry etching device. In other embodiments of the present disclosure, the operation of the gas extraction system will be changed according to the actual demands of the dry etching device. For example, in the flowchart of another embodiment of the present disclosure as shown in FIG. 10, in step S1010, the dry etching device performs a preparation operation of the etching process, and the gas extraction system enters the non-circulatory working mode at this time. In this embodiment, the gas extraction system opens all gas inlets under the non-circulatory working mode for extracting gas. Then, the dry etching device proceeds to step S1020 to perform the etching machining process, at this time, the gas extraction system enters the circulatory working mode accordingly and operates according to the set operation parameters. And then, the dry etching device proceeds to step S1030 to perform a post treatment operation and proceeds to step S1040 to deliver the machined substrate. In step S1030 and step S1040, the gas extraction system enters the non-circulatory working mode. After the dry etching device delivers the machined substrate, the dry etching device and the gas extraction system proceed to step S1050 and both is halted, and the entire etching machining process is terminated.

In step S1010 and step S1030 as shown in FIG. 10, the gas extraction system opens all gas inlets for extracting gas. This is because of that the S1020 etching step affects the etching uniformity in this embodiment, and the other steps are auxiliary steps. The dry etching device does not need to control the flow direction of the etching gas therein in step S1010 and step S1030, and if the gas extraction system executes the gas extraction cycle operation at this time, it will result in complicated time allocation of the gas extraction system. In other embodiments of the present disclosure, the dry etching device still needs to control the flow direction of the etching gas in the previous preparation of the etching process or the post treatment of the etching process. For example, in a plasma pretreatment procedure, light resistance on the surface of the workpiece needs to be removed by the plasma, and in this procedure, the uniformity of the workpiece needs to be controlled as well. Therefore, in similar cases, it needs to be specifically set when the gas extraction system enters in the circulatory working mode or non-circulatory working mode, according to the specific demands of the etching machining process of the dry etching device.

Although the implementations disclosed by the present disclosure are described above, the contents are merely implementations adopted to facilitate understanding of the present disclosure, rather than limiting the present disclosure. The method of the present disclosure can further have a variety of other embodiments, any skilled one who is familiar with this art could make a variety of corresponding variations and modifications without departing from the spirit of the present disclosure, but these corresponding variations and modifications shall fall within the scope of the present disclosure.

What is claimed is:

1. A dry etching device, comprising:
an etching cavity, including a base platform for placing a workpiece to be etched thereon; and
a gas extraction system arranged on the bottom of the etching cavity for controlling the movement of gas flow in the etching cavity, wherein the gas extraction system includes:
a gas passage provided with a plurality of gas inlets and a gas outlet, the gas inlets extending into the cavity through an opening located on the bottom of the cavity;
a gas extractor arranged in the gas passage and adjacent to the gas outlet; and
controllable valves, each mounted on a respective gas inlet and configured to be opened/closed according to setting parameters;
wherein the gas extraction system operates in a circulatory working mode or a non-circulatory working mode, and
under the circulatory working mode, the controllable valves are sequentially opened/closed at a certain time interval so as to control the flow direction of etching gas in the cavity, so that average densities of the etching gas flowing through the workpiece to be etched and thus contacting with different positions of the workpiece to be etched in a specific procedure are consistent.

2. The dry etching device as recited in claim 1, wherein under the non-circulatory working mode, all the controllable valves are opened to extract gas.

3. The dry etching device as recited in claim 1, wherein under the circulatory working mode, the controllable valves are controlled to gradually change the flow direction of etching gas in the cavity, in order to ensure the stability of the gas flow in the etching cavity.

4. The dry etching device as recited in claim 1, wherein under the circulatory working mode, the controllable valves are controlled to enable the gas extraction system to extract a constant volume of gas per unit time, in order to keep the pressure in the etching cavity unchanged.

5. The dry etching device as recited in claim 1, wherein under the circulatory working mode, the opening/closing time interval of the controllable valves is determined by the duration of the specific procedure.

6. The dry etching device as recited in claim 1, wherein the number and positions of the gas inlets are determined according to at least one of the shape of an electrode of the dry etching device, the shape of the base platform, and the shape of a surface to be etched of the workpiece.

7. The dry etching device as recited in claim 6, wherein the gas inlets are located on the bottom of the etching cavity, and are equidistantly arranged around the base platform.

8. The dry etching device as recited in claim 3, wherein under the circulatory working mode, the controllable valves on adjacent positions are controlled to alternatively open/close, so as to slowly change the flow direction of the etching gas in the cavity.

9. The dry etching device as recited in claim 4, wherein under the circulatory working mode, the controllable valves are controlled in such a manner that the increment of the gas extraction volume per unit time at the controllable valves during an opening process is equal to the decrement of the gas extraction volume per unit time at the controllable valves during a closing process, thus keeping the total volume of gas of the passage to be extracted per unit time unchanged.

10. The dry etching device as recited in claim 9, wherein under the circulatory working mode, the controllable valves are controlled in such a manner that the opening degrees of the controllable valves in an opening process are equal to the closing degrees of the controllable valves in a closing process.

11. A method for dry etching a workpiece, including the following steps:
placing a workpiece to be etched on a base platform in an etching cavity;
selecting a gas extraction mode from a group consisting of a circulatory working mode and a non-circulatory working mode according to procedures to be performed;
controlling, when the circulatory working mode is selected, the opening/closing of controllable valves according to setting parameters to control the flow direction of the etching gas, so as to make the average density of the etching gas contacting with different positions of the workpiece to be etched in a specific procedure tend to be consistent; and
performing a dry etching procedure while extracting gas in the circulatory working mode or non-circulatory working mode.

12. The method as recited in claim 11, wherein a gas extraction system of a dry etching device operates under the circulatory working mode when the dry etching device performs a main etching procedure.
